(19) United States
(12) Patent Application Publication
(10) Pub. No.: US 2012/0043628 A1
(43) Pub. Date: Feb. 23, 2012

(54) PACKAGED DEVICE INCLUDING A WELL FOR CONTAINING A DIE

(75) Inventors: Steve MARTIN, Fort Collins, CO (US); Timothy LECLAIR, Longmont, CO (US)

(73) Assignee: Avago Technologies Wireless IP (Singapore) Pte. Ltd., Singapore (SG)

(21) Appl. No.: 12/859,524

(22) Filed: Aug. 19, 2010

(51) Int. Cl. H01L 29/84; H01L 23/495

(52) U.S. Cl. 257/416; 257/676; 257/419; 257/E29.324; 257/E23.031

(57) ABSTRACT

A packaged device includes a package defining a well having a well top, a die positioned in the well of the package, and a retaining substrate attached to the package over the well top. The retaining substrate holds the die in direct contact with a portion of the package exposed at a well bottom opposite the well top.

### BACKGROUND

Performance of mechanical devices, such as transducers, may be affected by stress inherent within the device, as well as stress coupled or transferred to the device from the package that houses the device. This is particularly true of comparatively small devices, such as transducers manufactured using micro-electromechanical systems (MEMS) technology. For example, stress may be caused when a die, formed of silicon (Si), for example, has a coefficient of thermal expansion (CTE) different from the CTE of the package in which it is mounted. CTE indicates the rate or proportion of change of a material or structure with respect to changes in temperature. The difference between the die and package CTEs results in varying responses to changes in temperature, both during packaging processes and during operation. Even at the macro-scale, the placement of the MEMS device into a larger system may induce further stress in the MEMS device.

One conventional technique to package a die includes a plastic over-mold of a metal lead frame. In this configuration, the die is mounted onto the lead frame using a cured non-conductive adhesive and electrical connections are provided via bonding wires. The outer case of the package is then formed by placing the lead frame in a mold and injecting plastic to completely surround the die. For a MEMS device that requires an air cavity for operation, such as an acoustic transducer, a similar technique is used where plastic is molded around a lead frame without the die attached, leaving metal pads exposed for electrical contact and an opening in the package to enable subsequent inserting, attaching and wirebonding the die. An example of this technique is described by LECLAIR et al. in U.S. patent application Ser. No. 12/609,176, filed Oct. 30, 2009, the contents of which are hereby incorporated by reference.

FIG. 1 is a cross-sectional diagram of conventional packaged device 100. Referring to FIG. 1, die 110 is mounted to package 130, which includes lead frame 134 and plastic over-mold or plastic portion 136. Bonding wire 105 provides electrical connection between the lead frame 134 and a contact (not shown) on the die 110. The die 110 is physically connected to the lead frame 134 using a die attach adhesive 115. Typically, the die attach adhesive 115 is first dispensed on the lead frame 134, and then the die 110 is positioned and set into the die attach adhesive 115. The packaged device 100 is then cured at an elevated temperature. The cured die attach adhesive 115 does not prevent package induced stresses from coupling to the die 110.

### SUMMARY

In a representative embodiment, a packaged device includes a package defining a well having a well top, a die positioned in the well of the package, and a retaining substrate attached to the package over the well top. The retaining substrate holds the die in direct contact with a portion of the package exposed at a well bottom opposite the well top.

In another representative embodiment, a packaged device includes a lead frame, a plastic portion molded on the lead frame and defining a well, and a die positioned in the well of the package. A bottom surface of the die directly contacts a top portion of the lead frame exposed at a bottom of the well. The packaged device further includes an adhesive dispensed between at least one sidewall of the well and a corresponding at least one side the die. The adhesive holds the die in direct contact with the top portion of the lead frame exposed at the bottom of the well.

In another representative embodiment, a device package includes a lead frame, a plastic portion molded on the lead frame, and a well formed through a first surface of the plastic portion and exposing a portion of the lead frame, where the well contains a micro electro-mechanical system (MEMS) transducer device. The device package further includes a retaining substrate attached to the well, the retaining substrate holding the MEMS transducer device in direct contact with the exposed portion of the lead frame, and a pressure port formed through the lead frame and a second surface of the plastic portion opposite the well. The MEMS transducer device includes a membrane and a back-etched portion substantially aligned with the pressure port and an opening formed through the retaining substrate.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional diagram illustrating a conventional packaged device including a die.

FIG. 2A is a cross-sectional diagram illustrating a packaged device including a well for containing a die, according to a representative embodiment.

FIG. 2B is a top plan view illustrating the packaged device of FIG. 2A, according to a representative embodiment.

FIG. 3A is a cross-sectional diagram illustrating a packaged device including a well for containing a die, according to a representative embodiment.

FIG. 3B is a top plan view illustrating the packaged device of FIG. 2A, according to a representative embodiment.

FIG. 4 is a cross-sectional diagram illustrating a packaged device including a well for containing a die, according to a representative embodiment.

FIG. 5 is a cross-sectional diagram illustrating a packaged device including a well for containing a die, according to another representative embodiment.

FIGS. 6A and 6B are cross-sectional diagrams illustrating a packaged device including a well for containing a die, without a retaining substrate, according to a representative embodiment.

The FIGS. 7A-7F are top plan views illustrating an open end of a well formed in a package housing a die, according to representative embodiments.

FIG. 8A is a cross-sectional diagram illustrating a packaged device including a well for containing a die, without a retaining substrate, according to a representative embodiment.

FIG. 8B is a top plan view illustrating the packaged device of FIG. 8A, according to a representative embodiment.

FIG. 9A is a cross-sectional diagram illustrating a packaged device including a well for containing a die, without a retaining substrate, according to a representative embodiment.

FIG. 9B is a top plan view illustrating the packaged device of FIG. 9A, according to a representative embodiment.

FIG. 10 is a cross-sectional diagram illustrating a die consisting of a MEMS transducer, according to a representative embodiment.

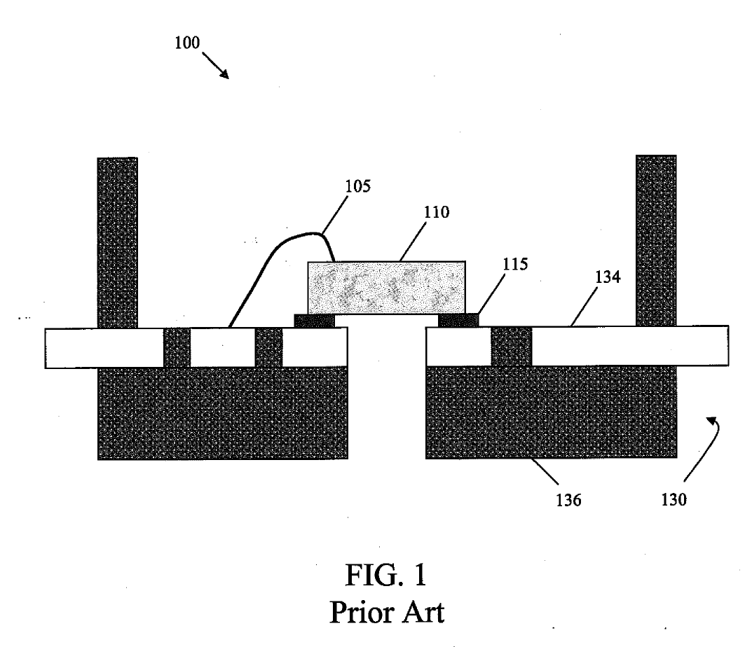

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper,” “lower,” “left,” “right,” “vertical” and “horizontal,” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be “below” that element. Likewise, if the device were rotated 90 degrees with respect to the view in the drawings, an element described as “vertical,” for example, would now be “horizontal.”

Packaging configurations are described herein that utilize low stress mounting techniques by placing a die, such as a MEMS transducer, in a well formed in the package. In various embodiments, the die is not physically attached, via adhesive or other means, to the package or to the well formed in the package. Rather, the die is held in position by a retaining substrate covering a top portion or opening of the well containing the die. In various alternative embodiments, rather than being held in position by a retaining substrate, the die is physically attached only to portions (e.g., one or more sidewalls) of the well formed in the package, but not to a top surface of the package in which the well is formed or to a lead frame of the package. Accordingly, stress transferred by the package to the die is reduced, controlled or repositioned.

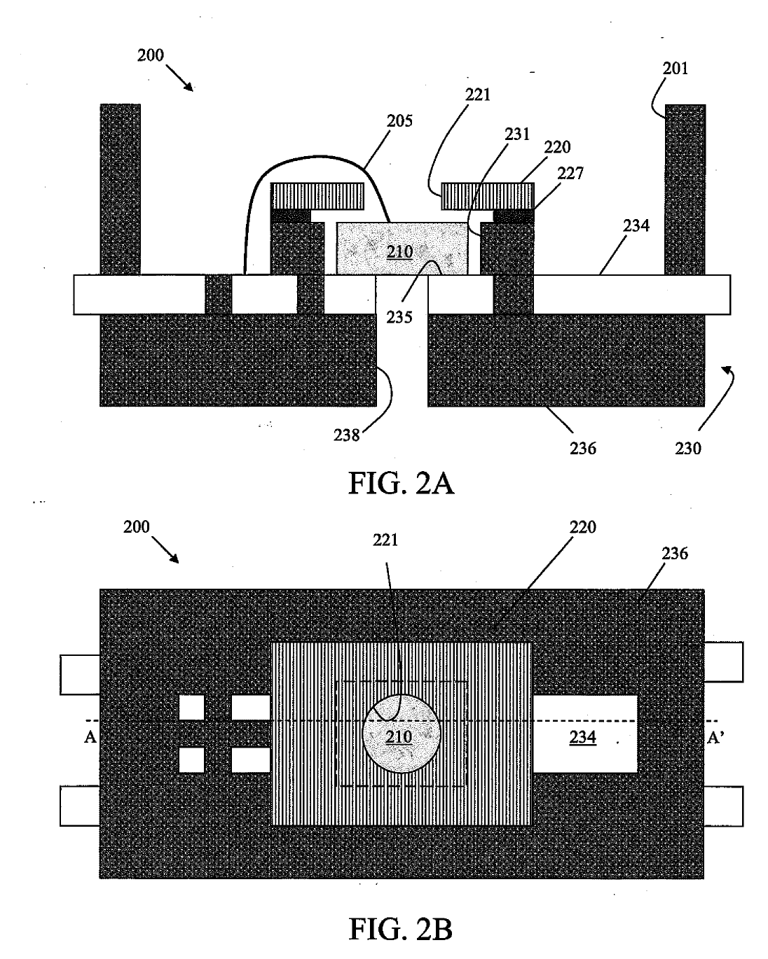

FIG. 2A is a cross-sectional diagram and FIG. 2B is a top plan view illustrating a package housing a die in a package well, according to a representative embodiment. More particularly, FIG. 2A is a cross-section of the package taken along line A-A′ shown in FIG. 2B.

Referring to FIGS. 2A and 2B, packaged device 200 includes die 210 housed within package 230, which includes lead frame 234 and plastic over-mold or plastic portion 236. The plastic portion 236 defines a well 231, which contains the die 210. The well 231 may be formed, for example, during a molding operation using a transfer mold to define the shape of the plastic portion 236. A retaining substrate 220 covers the open end or well top of the well 231 in order to hold the die 210 in position within the well 231. The retaining substrate 220 is attached to the package 230 at the well top of the well 231 via adhesive 227 or other attachment technique. The well 231, the die 210 and the retaining substrate 220 may be located within a larger package cavity 201 formed in the package 230.

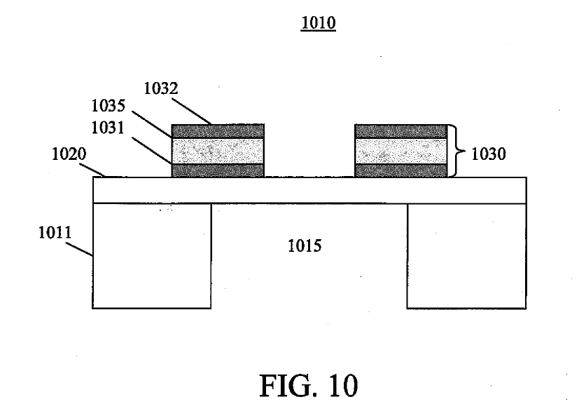

The retaining substrate 220 may be formed of any suitable material, such as metal, plastic, ceramic and/or semiconductor materials, such as Si. For example, the retaining substrate 220 may be formed of the same material as the package 230, discussed below. In the depicted embodiment, the retaining substrate 220 optionally includes a cut-out or opening 221 substantially centered over the die 210, which exposes a portion of a top surface of the die 210. The opening 221 enables access by representative bonding wire 205 to provide electrical connections between the lead frame 234 and contacts (not shown) on the die 210. Further, the opening 221 may be needed to enable proper operation of the die 210, for example, when the die 210 is a MEMS transducer, discussed below with reference to FIG. 10. Alternative configurations may include no opening 221, or different sizes and/or shapes of opening 221, without departing from the scope of the present teachings. For example, the opening 221 may be circular (as shown), square, rectangular, or any geometry suitable to meet desired specifications, as would be apparent to one of ordinary skill in the art.

A bottom surface of the die 210 is in direct contact with the lead frame 234 in the package 230 at the closed end or well bottom 235 of the well 231. More particularly, in the depicted embodiment, the die 210 abuts the top surface of the lead frame 234 to the extent it is exposed at the well bottom 235. In alternative configurations, the die 210 may contact the top surface of the plastic portion 236 (in addition to or instead of the top surface of the lead frame 234) exposed at the well bottom 235, without departing from the scope of the present teachings. Also, in the depicted embodiment, the die 210 is positioned over optional pressure port 238, formed through the lead frame 234 and the bottom portion of the plastic portion 236.

The die 210 being in direct contact with the top surface of the lead frame 234 means that there is no intervening layer of adhesive, solder, epoxy or other bonding material holding the die 210 to the lead frame 234. Rather, the die 210 is secured in place by the mechanical confines of the well 210 and the retaining substrate 220. Notably, FIG. 2A shows representative gaps between the sides of the die 210 and the sidewalls of the well 231, and between the top surface of the die 210 and the bottom surface of the retaining substrate 220. These gaps, which are exaggerated for clarity, indicate that the die 210 has limited freedom of movement within well 231 to avoid creation of stress points and otherwise to prevent or reduce stress induced on the die 210 by fluctuations or other changes in the package 230 caused, for example, by thermal expansion, vibration, bending, or the like.

The lead frame 234 of the package 230 may be formed from an electrically conductive material, such as various metals and metal alloys, including copper, nickel, aluminum, brass, copper/zinc alloys, and the like, or a combination thereof, for example. The material may be etched or stamped to form separate conductors, terminal leads, and the like, e.g., depending on application specific design requirements of various implementations, as would be apparent to one skilled in the art. The plastic portion 236 may be formed from a non-conductive material, such as various plastics or polymers, including liquid crystal polymer (LCP), polybutylene terephthalate (PBT), polypropylene (PP), polyphthalamide (PPA), and the like, for example. In various embodiments, the plastic portion 236 may include an integrated acoustic horn (not shown), formed over the pressure port 238 using transfer molding or other molding techniques, to support different environmental and operating conditions. Formation of a molded package and integrated acoustic horn is described, for example, by LECLAIR et al. in U.S. patent application Ser. No. 12/609,176, filed Oct. 30, 2009, the contents of which are hereby incorporated by reference.

In various embodiments, the die 210 may be a transducer device, such as an ultrasonic MEMS acoustic transducer or piezoelectric MEMS ultrasonic transducer (PMUT), for example, although other types of dies, including various types of semiconductor devices, may be incorporated without departing from the scope of the present teachings. The die 210 may include various materials, such as Si, that differ from the material(s) of the package 230 (and thus have differing CTEs, for example).

FIG. 10 is a cross-sectional diagram illustrating an example of die 210, according to a representative embodiment. In particular, FIG. 10 depicts MEMS transducer 1010, which includes transducer substrate 1011, membrane 1020 and resonator or resonator stack 1030, where the membrane 1020 and the resonator stack 1030 form an active transducer, e.g., over cavity 1015 formed through a backside of the transducer substrate 1011. In the depicted embodiment, the membrane 1020 is formed of a single layer of membrane material, although the membrane 1020 may have multiple layers without departing from the scope of the present teachings.

The resonator stack 1030 includes first electrode 1031 disposed over a portion of the membrane 1020, and piezoelectric layer 1035 and second electrode 1032 stacked on the first electrode 1031. The piezoelectric layer 1035 may be formed from aluminum nitride, lead zirconate titanate (PZT), or other film compatible with semiconductor processes. The first and second electrodes 1031, 1032 may be formed from a metal compatible with semiconductor processes, such as molybdenum, tungsten, aluminum or a combination thereof.

The resonator stack 1030 is shown as an annular resonator, where the cross-section is taken across the center. The annular resonator stack 1030 may be substantially circular in shape, for example, although it may be formed in different shapes, such as ovals, squares, rectangles, or the like, without departing from the scope of the present teachings. Further, in various embodiments, the resonator stack 1030 need not have an annular shape, but may simply be a solid resonator stack on the substrate 1011. The resonator stack 1030 is substantially centered over the cavity 1015, enabling mechanical movement of the membrane 1020 and/or the resonator stack 1030.

The transducer substrate 1011 may be formed of various types of materials compatible with semiconductor processes, such as Si, gallium arsenide (GaAs), indium phosphide (InP), glass, sapphire, alumina, or the like, which is useful for integrating connections and electronics, thus reducing size and cost. The cavity 1015 formed through the transducer substrate 1011 may be substantially the same shape as the resonator stack 1030, e.g., circular, although it may have any of a variety of sizes and shapes, such as oval, square, rectangular, or the like, without departing from the scope of the present teachings. The cavity 1015 may be obtained by back side etching the bottom surface of the transducer substrate 1011, which may include a dry etch process, such as a Bosch process, for example, although various alternative techniques may be incorporated. Formation of the transducer substrate 1011 and the resonator stack 1030 (on a membrane) is described, for example, by MARTIN et al. in U.S. patent application Ser. No. 12/495,443, which is hereby incorporated by reference.

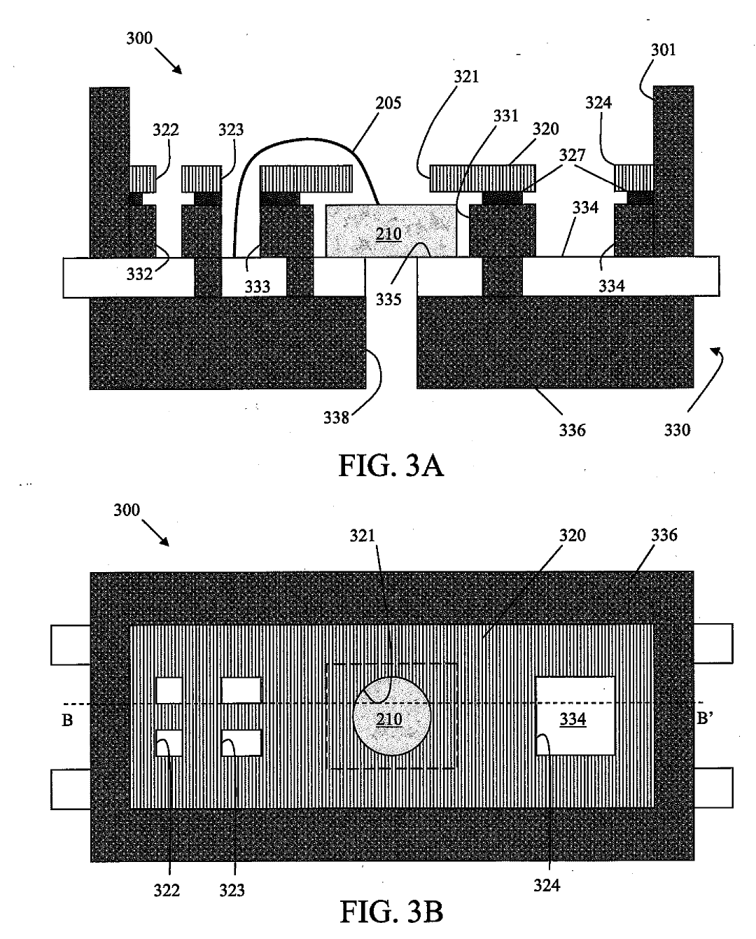

FIG. 3A is a cross-sectional diagram and FIG. 3B is a top plan view illustrating a package housing a die in a package well, according to a representative embodiment. More particularly, FIG. 3A is a cross-section of the package taken along line B-B′ shown in FIG. 3B.

Referring to FIGS. 3A and 3B, packaged device 300 includes die 210 housed within package 330, which includes lead frame 334 and plastic over-mold or plastic portion 336. The plastic portion 336 defines a well 331, which contains the die 210. A retaining substrate 320 covers the open end or well top of the well 331 in order to hold the die 210 in position within the well 331. As discussed above, the bottom surface of the die 210 is in direct contact with a top surface of the lead frame 334 exposed at the closed end or well bottom 335 of the well 331, in that there is no adhesive, solder, epoxy or other bonding material securing the die 210 directly to the top surface of the lead frame 334. Also, in the depicted embodiment, the die 210 is positioned over (optional) pressure port 338 formed through the lead frame 334 and the plastic portion 336.

The packaged device 300, including the associated components and materials, of FIGS. 3A and 3B is similar to the packaged device 200 of FIGS. 2A and 2B, discussed above, except that retaining substrate 320 is larger than the retaining substrate 220, and thus fits substantially the entire package cavity 301. Accordingly, the retaining substrate 320 may be used for self-alignment purposes during assembly. Also, the retaining substrate 320 provides more area for bonding, e.g., through adhesive attachment, of the retaining substrate 320 to the package 330. For example, in order to support the entire retaining substrate 320, the plastic portion 336 may be built up throughout the package cavity 301, rather than just at the location of the well 331. Accordingly, the plastic portion 336 includes additional openings to expose desired portions of the lead frame 334, indicated by representative lead frame openings 332, 333 and 334. Thus, in various embodiments, the retaining substrate 320 is attached to the package 330 via adhesive 327 applied throughout the package cavity 301, and not just surrounding the well 331.

The retaining substrate 320 includes opening 321 substantially centered over the die 210, which exposes a portion of a top surface of the die 210, as discussed above with reference to the opening 221. Also, the retaining substrate 320 includes additional representative openings 322, 323 and 324 corresponding to the lead frame openings 332, 333 and 334 to expose the portions of the lead frame 334 for wirebonding or other purposes. Of course, alternative configurations may include no openings 321-324, or different numbers, sizes and/or shapes of openings 321-324, without departing from the scope of the present teachings.

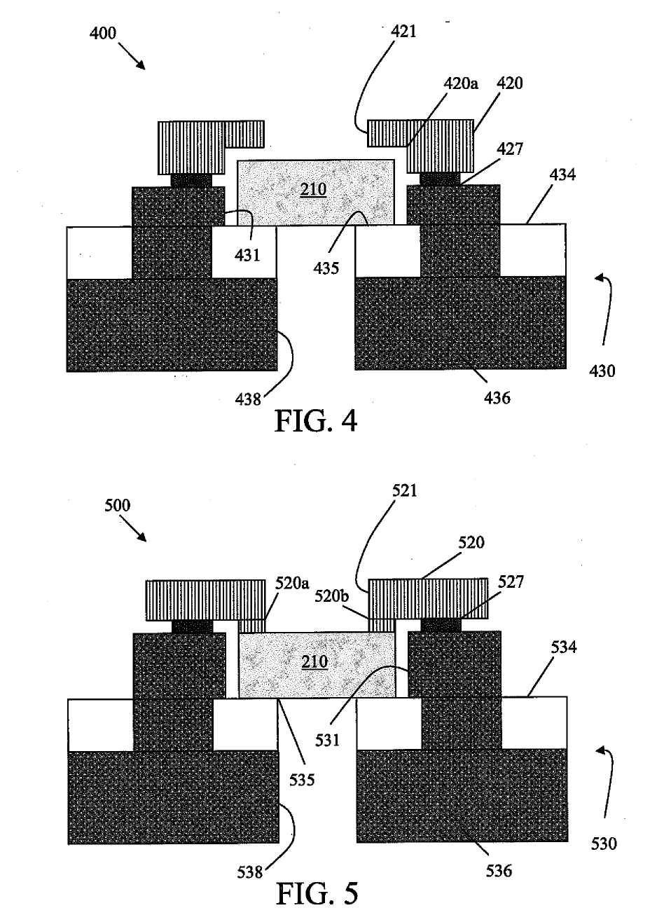

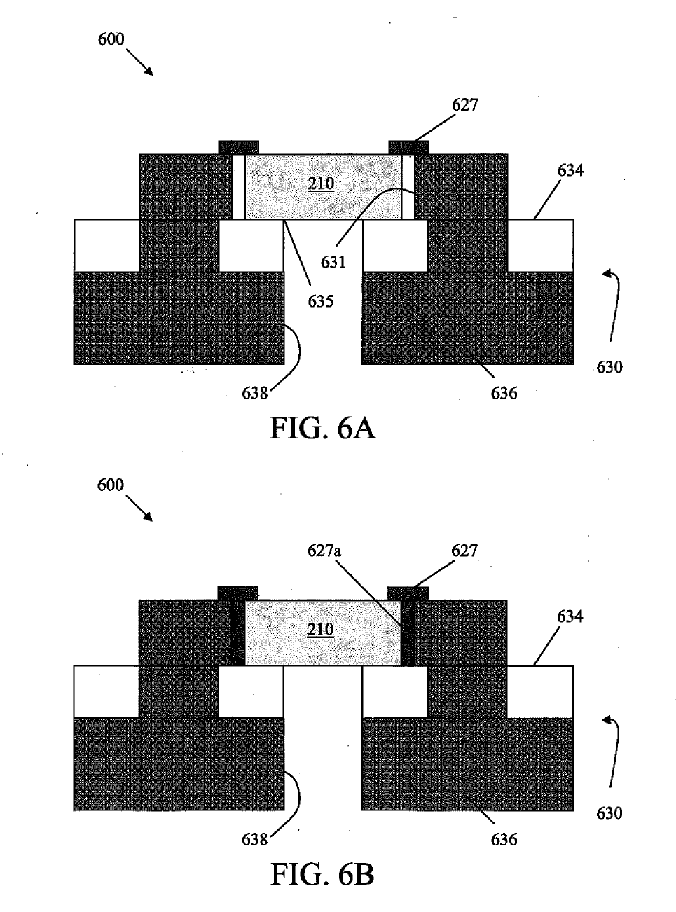

Various embodiments incorporate alternative means for securing a die within a package well using a retaining substrate, in order to enhance contact between the die and the package (e.g., the lead frame), while maintaining sufficient freedom of movement of the die to avoid creation of stress points and otherwise to prevent or reduce stress induced by the package onto the die. FIGS. 4 and 5 provide examples of various embodiments, discussed below. For simplicity of explanation, FIGS. 4 and 5 show only portions of the packaged devices surrounding the corresponding package wells, in which the dies are housed, respectively.

FIG. 4 is a cross-sectional diagram illustrating a packaged device including a well for containing a die, according to a representative embodiment. More particularly, packaged device 400 includes die 210 housed within package 430, which includes lead frame 434 and plastic over-mold or plastic portion 436.

The plastic portion 436 defines a well 431, which contains the die 210. A retaining substrate 420 covers the open end or well top of the well 431 in order to hold the die 210 in position within the well 431. As discussed above, the bottom surface of the die 210 is in direct contact with a top surface of the lead frame 434 at the closed end or well bottom 435 of the well 431, in that there is no adhesive, solder, epoxy or other bonding material securing the die 210 directly to the top surface of the lead frame 434. Also, in the depicted embodiment, the die 210 is positioned over (optional) pressure port 438 formed through the lead frame 434 and the plastic portion 436.

The packaged device 400 of FIG. 4, including the associated components and materials, is similar to the packaged device 200 of FIGS. 2A and 2B, discussed above, except that retaining substrate 420 includes a projection over the die 210 that creates notch 420a, which has a shape complementary to the top edges of the die 210. The retaining substrate 420 thus provides additional positioning control through alignment of the die 210 within the notch 420a. For example, manufacturing processes may provide greater dimensional precision with respect to forming the notch 420a and opening 421 in the retaining substrate 420, than with respect to forming the well 431 in the plastic portion 436. In this case, incorporation of the notch 420a better controls positioning within desired specifications, while still maintaining some freedom of movement of the die 210. The opening 421 may be formed in the retaining substrate 420, if needed, to expose a portion of a top surface of the die 210, as discussed above with reference to the opening 221. The retaining substrate 420 is attached to the plastic portion 436 at the open end of the well 431 via adhesive 427.

FIG. 5 is a cross-sectional diagram illustrating a packaged device including a well for containing a die, according to another representative embodiment. More particularly, packaged device 500 includes die 210 housed within package 530, which includes lead frame 534 and plastic over-mold or plastic portion 536.

The plastic portion 536 defines a well 531, which contains the die 210. A retaining substrate 520 covers the open end or well top of the well 531 in order to hold the die 210 in position within the well 531. As discussed above, the bottom surface of the die 210 is in direct contact with a top surface of the lead frame 534 at the closed end or well bottom 535 of the well 531, in that there is no adhesive, solder, epoxy or other bonding material securing the die 210 directly to the top surface of the lead frame 534. Also, in the depicted embodiment, the die 210 is positioned over (optional) pressure port 538 formed through the lead frame 534 and the plastic portion 536.

The packaged device 500 of FIG. 5, including the associated components and materials, is similar to the packaged device 200 of FIGS. 2A and 2B, discussed above, except that retaining substrate 520 includes one or more stand-offs, indicated by representative stand-offs 520a and 520b, which extend from a bottom surface of the retaining substrate 520 to contact the top surface of the die 210. The stand-offs 520a and 520b may be separate extensions or pillars that contact the die 210 at corresponding discrete locations. Alternatively, the stand-offs 520a and 520b may form a single, annular extension that contacts the dies along its entire circumference. Of course, the number, shapes and arrangement of the stand-offs 520a and 520b may vary without departing from the scope of the present teachings.

In an embodiment, the stand-offs 520a and 520b are formed of the same material as the retaining substrate 520, and thus may be integral with the retaining substrate 520. However, the stand-offs 520a and 520b may be formed of any suitable material and/or may be formed separately from the retaining substrate 520. For example, in an alternative embodiment, the stand-offs 520a and 520b are formed of a compressible material, such as foam (e.g., weather stripping), rubber, specially designed plastic or metal spring structures, and plastic or retaining cantilevers, or the like, attached to the retaining substrate 520. The compressible material applies constant pressure to the die 210 toward the top surface of the lead frame 534 exposed at the well bottom 535 to hold the die 210 in position, but does not allow for the transference of stress from the package 530 to the die 210.

The retaining substrate 520 thus provides additional positioning control by exerting downward pressure on the die 210, or otherwise further confining movement of the die 210 in a direction parallel to the side walls of the well 531, by virtue of the stand-offs 520a and 520b. For example, the stand-offs 520a and 520b may compensate for added thickness resulting from application of the adhesive 527 between the retaining substrate 520 and the plastic portion 536. An opening 521 may be formed in the retaining substrate 520, if needed, to expose a portion of the top surface of the die 210, as discussed above with reference to the opening 221.

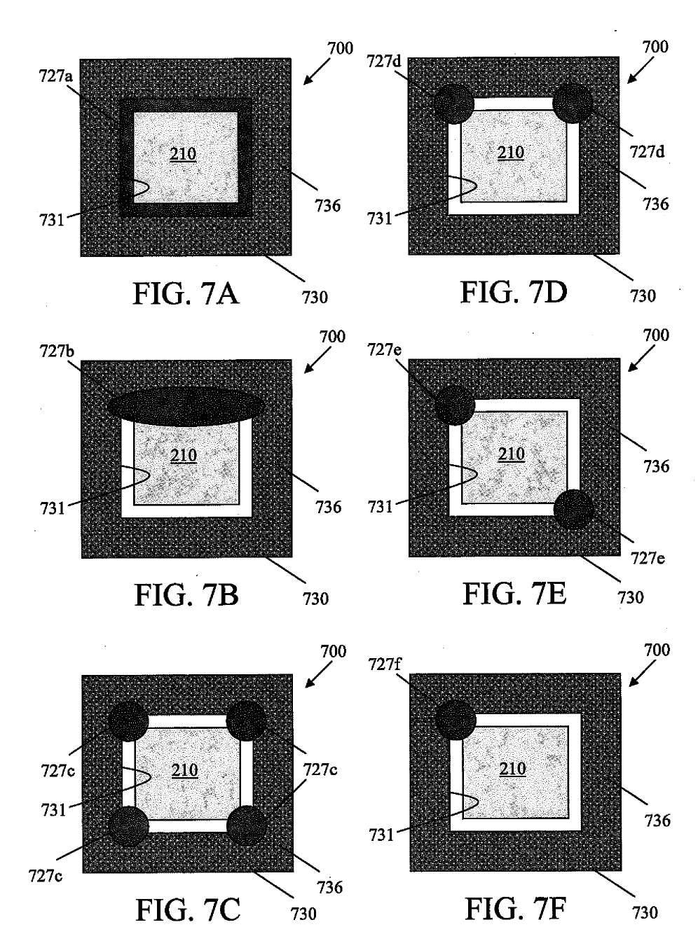

Various alternative embodiments enable securing a die within a package well without use of a retaining substrate, while reducing and/or controlling stress induced by the package onto the die. FIGS. 6A-6B, 7A-7F, 8A-8B and 9A-9B provide examples of various embodiments, discussed below. For simplicity of explanation, FIGS. 6A-6B, 7A-7F, 8A-8B and 9A-9B show only portions of the package devices surrounding the corresponding package wells, in which the dies are housed, respectively.

FIGS. 6A and 6B are cross-sectional diagrams illustrating a packaged device including a well for containing a die, without a retaining substrate, according to a representative embodiment. More particularly, packaged device 600 includes die 210 housed within package 630, which includes lead frame 634 and plastic over-mold or plastic portion 636.

The plastic portion 636 defines a well 631, shown in FIG. 6A, which contains the die 210. As discussed above, the bottom surface of the die 210 is in direct contact with a top surface of the lead frame 634 at the closed end or well bottom 635 of the well 631, in that there is no adhesive, solder, epoxy or other bonding material securing the die 210 directly to the top surface of the lead frame 634. Also, in the depicted embodiment, the die 210 is positioned over (optional) pressure port 638 formed through the lead frame 634 and the bottom surface of the plastic portion 636.

The packaged device 600 of FIGS. 6A and 6B, including the associated components and materials, is similar to the packaged device 200 of FIGS. 2A and 2B, discussed above, except that there is no retaining substrate covering the open end of the well 631. Thus, the well 631 is employed to align the die 210 in the package 630. In order to hold the die 210 in position within the well 631, adhesive 627 is dispensed at the open end of the well 631 over gaps between the sides of the die 210 and corresponding sidewalls of the well 631, as shown in FIG. 6A. The adhesive 627 is uncured when initially dispensed, and therefore descends into the gaps between the sides of the die 210 and the sidewalls of the well 631, indicated by descended adhesive 627a shown in FIG. 6B. When subsequently cured, the adhesive 627, 627a holds the die 210 in position within the well 631 and in contact with the package 630, thus restricting movement of the die 210 without the bottom surface of the die 210 being physically attached or bonded to the lead frame 634. In the depicted embodiment, since there is no retaining substrate, the top surface of the die 210 is exposed, e.g., enabling connection of the bonding wires (not shown in FIGS. 6A and 6B).

Without the retaining substrate, the adhesive may be selectively applied in various locations in the well to help control transfer of stress from the package to the die. The FIGS. 7A-7F are top plan views illustrating an open end of a well formed in a package housing a die, according to representative embodiments. More particularly, FIGS. 7A-7F show examples of alternative adhesive dispensing geometries enabled by the well structure.

Referring to FIGS. 7A-7F, packaged device 700 includes die 210 positioned within well 731, which is formed in plastic portion 736 of package 730. The packaged device 700, including the associated components and materials, is similar to the packaged device 200 of FIGS. 2A and 2B, discussed above, except that there is no retaining substrate covering the open end of the well 731, and thus adhesive is applied to hold the die 210 in position.

In FIG. 7A, adhesive 727a is applied substantially uniformly around the perimeter of the die 210 within the well 731, which is similar to the application of adhesive 627a discussed above with reference to FIG. 6B. In other words, the adhesive 727a is dispensed between the sides of the die 210 and the sidewalls of the well 731. This substantially uniform application of the adhesive 727a results in relatively even distribution of stress induced by the package 730 on the die 210. Thus, the die 210 maintains substantially the same relative position with respect to the package 730 and/or the well 731.

In FIG. 7B, adhesive 727b is applied only on one edge of the die 210. Therefore, the adhesive 727b is dispensed between only one side of the die 210 and one sidewall of the well 731. The die 210 is therefore connected by the adhesive 727b on only one of its four sides, as well as along one top edge to the extent the adhesive 727b overlaps the top surfaces of the die 210 and the well 731 (indicated by the oval shape of the adhesive 727b). This non-uniform application of the adhesive 727b results in stress induced by the package 730 on the die 210 having an asymmetric stress profile. This allows the die 210 to expand or shrink unconstrained in a single direction, while the orthogonal direction is constrained by the adhesive.

In FIG. 7C, adhesive 727c is applied to each of the four corners of the die 210. Therefore, the adhesive 727c is dispensed between the corners of the die 210 and corresponding corners of the sidewalls of the well 731. The die 210 is therefore connected by the adhesive 727c along each edge running parallel to the sidewalls of the well 731, as well as on the corners of the top surface of the die 210 to the extent the adhesive 727c overlaps the top surfaces of the die 210 and the well 731 (indicated by the circular shapes of the adhesive 727c). Because the adhesive 727c is applied at only the four corners, stress induced by the package 730 has less effect on the die 210 due to a relatively weak coupling.

FIGS. 7D-7F are variations of the arrangement depicted in FIG. 7C, where adhesive is applied to fewer than all four corners of the die 210, resulting in non-uniform distribution of stress induced by the package 730 to the die 210. The various configurations allow for expansion or contraction due to CTE to propagate unconstrained in vertical axis, diagonal axis, or all axes, respectively. In FIG. 7D, adhesive 727d is applied to two adjacent corners of the die 210. Therefore, the adhesive 727d is dispensed between these corners and the corresponding corners of the sidewalls of the well 731. In FIG. 7E, adhesive 727e is applied to two opposite corners of the die 210. Therefore, the adhesive 727e is dispensed between these corners and the corresponding corners of the sidewalls of the well 731. In FIG. 7F, adhesive 727f is applied to only one corner of the die 210. Therefore, the adhesive 727f is dispensed between only this corner and the corresponding corner of the sidewalls of the well 731. These non-uniform applications of the adhesive 727d, 727e and 727f result in stress induced by the package 730 on the die 210 having a skewing, tilting or other non-uniform effect on the relative position of the die 210 with respect to the package 730 and/or the well 731.

In other embodiments, the well itself may have features that direct and contain adhesive in predetermined locations. That is, the sidewalls of the well formed in the package may include cambers with notches, protrusions or other features that help align and secure the die within the well, and/or to reduce stress induced from the package to the die.

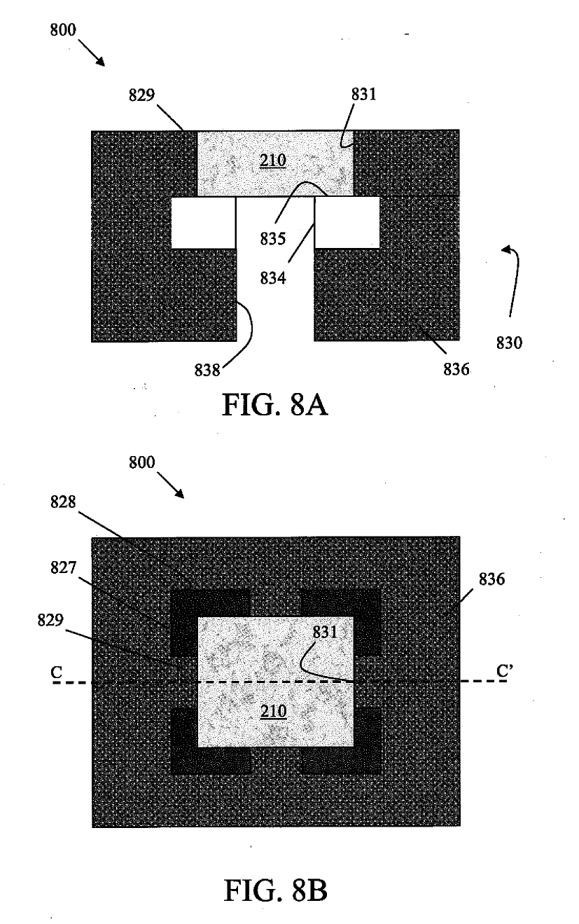

For example, FIG. 8A is a cross-sectional diagram and FIG. 8B is a top plan view illustrating a packaged device including a well having adhesive containment features for containing a die, without a retaining substrate, according to a representative embodiment. More particularly, FIG. 8A is a cross-section of the package taken along line C-C′ shown in FIG. 8B.

Referring to FIGS. 8A and 8B, packaged device 800 includes die 210 housed within package 830, which includes lead frame 834 and plastic over-mold or plastic portion 836. Also, the die 210 may be positioned over (optional) pressure port 838 formed through the lead frame 834 and the plastic portion 836. The plastic portion 836 defines a well 831, which contains the die 210. As discussed above, the bottom surface of the die 210 is in direct contact with a top surface of the lead frame 834 of the package 830 at the closed end or well bottom 835 of the well 831. The packaged device 800 of FIGS. 8A and 8B, including the associated components and materials, is similar to the packaged device 200 of FIGS. 2A and 2B, discussed above, except that there is no retaining substrate covering the open end of the well 831 and the well 831 includes containment features.

In the depicted embodiment, protrusions 829 extend from each of the sidewalls of the well 831, creating pockets 828 at each corner of the die 210 to contain the adhesive 827. The protrusions 839 physically align the die 210 within the well 831 of the package 830. The adhesive 827 is dispensed in the pockets 828, as shown in FIG. 8B, in order to hold the die 210 in position within the well 831 and in contact with the package 830, without being physically attached or bonded to the lead frame 834. In the depicted embodiment, since there is no retaining substrate, the top surface of the die 210 is exposed, e.g., enabling connection of the bonding wires (not shown in FIGS. 8A and 8B).

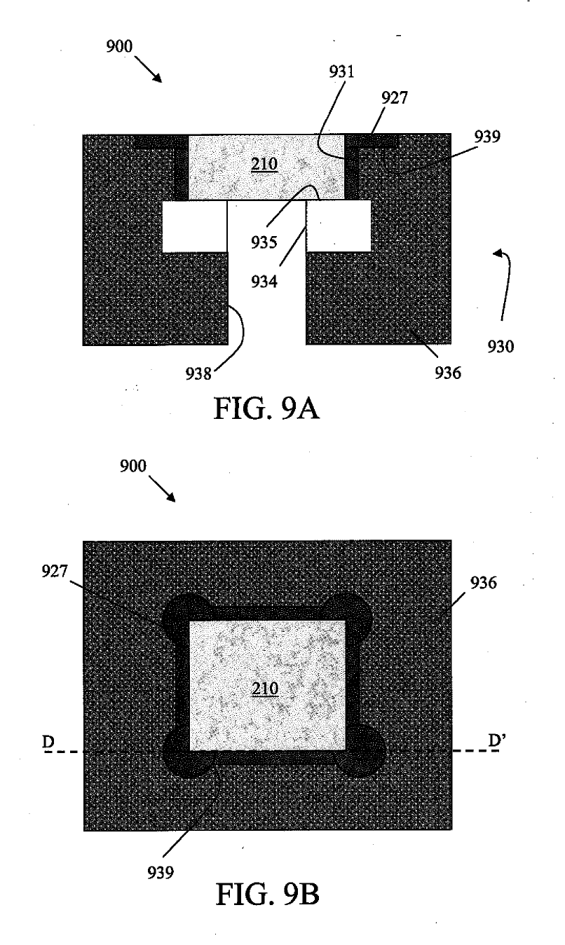

Similarly, FIG. 9A is a cross-sectional diagram and FIG. 9B is a top plan view illustrating a packaged device including a well having adhesive containment features for containing a die, without a retaining substrate, according to a representative embodiment. More particularly, FIG. 9A is a cross-section of the package taken along line D-D′ shown in FIG. 9B.

Referring to FIGS. 9A and 9B, packaged device 900 includes die 210 housed within package 930, which includes lead frame 934 and plastic over-mold or plastic portion 936. Also, the die 210 may be positioned over (optional) pressure port 938 formed through the lead frame 934 and the bottom surface of the plastic portion 936. The plastic portion 936 defines a well 931, which contains the die 210. As discussed above, the bottom surface of the die 210 is in direct contact with a top surface of the lead frame 934 of the package 930 at the closed end or well bottom 935 of the well 931. The packaged device 900 of FIGS. 9A and 9B, including the associated components and materials, is similar to the packaged device 200 of FIGS. 2A and 2B, discussed above, except that there is no retaining substrate covering the open end of the well 931 and the well 931 includes containment features.

In the depicted embodiment, notches 939 are formed at each of the corners of the well 931. The adhesive 927 is dispensed within the notches 929 and along the sidewalls of the well 931, e.g., as discussed above with reference to FIGS. 6A and 6B, in order to hold the die 210 in position within the well 931 and in contact with the package 930, without being physically attached or bonded to the top surface of the lead frame 934. In the depicted embodiment, the notches 939 are relatively shallow in comparison to the depth of the well 931 and substantially circular, although the notches 929 may have different sizes and/or shapes without departing from the scope of the present teachings. Also, since there is no retaining substrate, the top surface of the die 210 is exposed, e.g., enabling connection of the bonding wires (not shown in FIGS. 9A and 9B).

The packaged device having a well for containing a die may be fabricated and assembled according to various techniques, e.g., compatible with semiconductor processes. For example, referring again to FIGS. 2A and 2B, the lead frame 234 may be etched to provide a desired pattern of conductors, terminal leads and other features, e.g., as shown in FIG. 2B. The etching may include chemical etching using photolithography, for example, although various alternative techniques may be incorporated. The etched lead frame 234 may be plated for wirebonding, for example, using an optimized plating material, such as nickel and/or gold, to permit gold or aluminum bonding wire attachment. The bonding wires, indicated by bonding wire 205, provide electrical interconnections from the die 210 to the lead frame 234.

A molding operation is performed on the lead frame 234 to form plastic portion 236 on and around the lead frame 234. The molding operation may include placing the lead frame 234 in a transfer mold previously formed to define the shape of the plastic portion 236, including formation of the well 231. A polymer, e.g., LCP, PBT, PP, or PPA, is then transfer molded, for example, to encapsulate the lead frame 234 and simultaneously to form the well 231. The polymer is typically a solid at room temperature, and melted prior to transfer to the mold. The shape of the well, including various protrusions or notches, e.g., as discussed above with reference to FIGS. 8A-8B and 9A-9B, is defined by the shape of the machined transfer mold. The cooled (after melting) mold plastic will assume the desired shape within the transfer mold. Accordingly, the plastic portion 236 and the well 231 are integrally formed to surround the lead frame 234 during the molding operation.

The die 210 is then inserted into the well 231, such that a bottom surface of the die 210 is in direct contact with the top surface of the lead frame 234 at the closed end or well bottom 235 of the well 231, as discussed above. Adhesive 227 is applied to the open end or well top of the well 231, and the retaining substrate 220 is placed on the adhesive 227 to attach the retaining substrate 220 to the plastic portion 236 via the open end of the well 231. The adhesive 227 may then be cured at an elevated temperature. In alternative embodiments, the retaining substrate 220 may be attached using various techniques, such as epoxy bonding, soldering, ultrasonic welding, and the like. The retaining substrate 220 may be previously fabricated to include the opening 221, which is substantially centered over the die 210.

Wirebonding may then be performed, during which representative bonding wire 205 is connected between pads (not shown) on the die 210 and the conductor pattern of the lead frame 234 via lead terminals (not shown). The pads on the die 210 may be top pads, for example, electrically connected to the top electrodes of an acoustic transducer (e.g., as shown in FIG. 10) of the die 210. The die 210 may be previously fabricated for attachment to the lead frame 234. A lid (not shown) may be attached over the package cavity 201. The lid may be previously formed, for example, using a molding process similar to the transfer molding process of the plastic portion 236, described above. In an embodiment, the lid may be mechanically attached to the plastic portion 236 by press fitting, for example, or using an epoxy adhesive, for example, creating a hermetically sealed environment.

According to various embodiments, a well formed in a package precisely positions a die within the package, while reducing and controlling stress induced on the die from the package. For example, the well enables the die to be securely held in place without rigid adhesive connecting the die to a surface of the package lead frame. Also, the package well enables placement of adhesive, e.g., on all or portions of sidewalls of the well, to control manner in which stress is transferred to the die.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A packaged device, comprising:
a package defining a well having a well top;
a die positioned in the well of the package; and
a retaining substrate attached to the package over the well top, the retaining substrate holding the die in direct contact with a portion of the package exposed at a well bottom opposite the well top.

2. The device of claim 1, wherein the package comprises a lead frame and a plastic portion at least partially encasing the lead frame, the well being formed in the plastic portion of the package.

3. The device of claim 2, wherein the lead frame comprises the portion of the package exposed at the well bottom in direct contact with the die.

4. The device of claim 1, wherein the die comprises a micro electro-mechanical system (MEMS) device.

5. The device of claim 4, wherein the MEMS device comprises an acoustic transducer configured to convert between electrical energy and the acoustic signals.

6. The device of claim 5, wherein the retaining substrate defines an opening exposing a portion of a first surface of the die.

7. The device of claim 6, wherein the package further defines a pressure port having an open end on an opposite surface of the package than the open end of the well, the pressure port exposing a portion of a second surface of the die.

8. The device of claim 6, wherein the retaining substrate comprises a notch along the opening in the retaining substrate for securing the die in position.

9. The device of claim 1, wherein the retaining substrate is attached to the well top via an adhesive.

10. The device of claim 1, wherein the package further defines a package cavity in which the well is formed, the retaining substrate self-aligning with the package cavity.

11. The device of claim 1, further comprising:
a stand-off extending from the retaining substrate and contacting the die, the stand-off securing the die in position.

12. The device of claim 11, wherein the stand-off comprises a compressible material which applies pressure to the die for securing the die in position.

13. The device of claim 2, wherein the plastic portion comprises at least one of liquid crystal polymer (LCP), polybutylene terephthalate (PBT), polypropylene (PP), polyphthalamide (PPA).

14. The device of claim 2, wherein the die comprises at least one contact pad connected to the lead frame via at least one corresponding bonding wire.

15. A packaged device, comprising:
a lead frame;
a plastic portion molded on the lead frame and defining a well;
a die positioned in the well of the package, a bottom surface of the die directly contacting a top portion of the lead frame exposed at a bottom of the well; and
an adhesive dispensed between at least one sidewall of the well and a corresponding at least one side the die, the adhesive holding the die in direct contact with the top portion of the lead frame exposed at the bottom of the well.

16. The device of claim 15, further comprising:
protrusions extending from sidewalls of the well, the protrusions forming at least one pocket for containing the adhesive.

17. The device of claim 15, further comprising:
at least one notch formed in a top of the well, the at least one notch containing a portion of the adhesive.

18. A device package, comprising:
a lead frame;
a plastic portion molded on the lead frame;
a well formed through a first surface of the plastic portion and exposing a portion of the lead frame, the well containing a micro electro-mechanical system (MEMS) transducer device;
a retaining substrate attached to the well, the retaining substrate holding the MEMS transducer device in direct contact with the exposed portion of the lead frame; and
a pressure port formed through the lead frame and a second surface of the plastic portion opposite the well,
wherein the MEMS transducer device comprises a membrane and a back-etched portion substantially aligned with the pressure port and an opening formed through the retaining substrate.

19. The package of claim 18, further comprising:
a stand-off between the retaining substrate and the die for securing the contact between the die and the exposed portion of the lead frame.

20. The device of claim 19, wherein the stand-off comprises a compressible material, which applies pressure to the die.
